(19) United States
(12) Patent Application Publication
(10) Pub. No.: US 2002/0096625 A1
(43) Pub. Date: Jul. 25, 2002

(54) Apparatus and method for output signal with corresponding bias of photocells in linear CMOS sensor

(75) Inventor: Chen-Ho Lee, Hsin-Chu City (TW)

Correspondence Address: LOWE HAUPTMAN GILMAN & BERNER, LLP, Suite 310, 1700 Diagonal Road,, Alexandria, VA, 22314, US

(73) Assignee: UMAX DATA SYSTEMS INC.

(21) Appl. No.: 09/768,614

(22) Filed: Jan. 25, 2001

(51) Int. Cl. H01L 27/00

(52) U.S. Cl. 250/208.1

(57) ABSTRACT

Apparatus for output in combination of an image data signal and a corresponding bias signal in a linear CMOS sensor is provided. The apparatus comprises enabling circuits for enabling first switch devices of the photocells. Each first switch device is on a bypass of an access from the photocell to a second switch device and the second switch device on an access for the photocell to a common bus. A method for output in combination of an image data signal and a corresponding bias signal in a linear CMOS sensor of a scanner is provided. The method comprises providing photocells arranged in a row that each photocell has an access to a common bus controlled by a corresponding first switch device. Each photocell further has a bypass of the access controlled by a corresponding second switch device. The first switch devices are enabled by a plurality of control lines that each control line is from a corresponding AND gate that makes AND operation for a corresponding pixel select line and a common reset line.

### BACKGROUND OF THE INVENTION

1. Field of the Invention

The invention relates to apparatus and a method for output signals in a linear CMOS sensor, and more particularly related to an output signal in combination of image data signal and corresponding bias signal for each photocell in the linear CMOS sensor applied on a scanner.

2. Description of the Prior Art

Solid state image sensors are presently realized in two common forms: Charge Coupled Devices (CCDs) and MOS diode arrays. Both forms require specialized fabrication processes to suit them for image sensing and both forms also require substantial electronic circuits external to the sensing chip in order to drive the arrays and to process the output signal. A complete sensor subsystem therefore typically requires an assembly of many components with consequent implications of high production cost, power consumption and physical size.

Traditionally, solid state based scanners are realized charge-coupled devices (CCDs) as image capturing devices. Unfortunately, CCD technology is not compatible with standard DC processes for portable scanner development. In addition, CCDs use high voltage clock signals, implying correspondingly high power dissipation levels. Therefore, there is much interest in scanner using standard CMOS processes, which would promote integration and low power consumption.

Linear diode sensors are commonly based on a one dimensional row of photodiodes implemented as the reverse-biased semiconductor junctions of the type normally used to form the source and drain regions of MOS transistors. A high reverse bias is applied and the diode then is electrically isolated and exposed to light or other radiation to be detected. Incident radiation increases the reversed-bias leakage current to the diode and this current is effectively integrated on the reverse-bias capacitance of the isolated junction causing a reduction in the reverse-bias potential. The use of such techniques for conversion of radiation to electronic charge and potential is well known and practiced. In particular this technique is used in MOS linear diode type sensors. In these sensors a single MOS transistor controls access to the diode for the purpose of writing to the cell (that is, resetting to a high reverse-bias) and reading from it by connecting the diode to a bit-line (i.e. sense line) and thence ultimately to charge-sensing circuits which convert the charge stored within the cell to an output voltage.

Typically the linear, same as array, also can be accessed in scan-line format whereby the linear is read as consecutive pixels. This process is also commonly practiced and involves enabling a row of cells by a “word-line” which is connected in common to the access transistor gates of all cells in the row. Digital circuitry is used to generate and to drive the necessary pattern of word-line signals. Normally this circuitry may take the form of a shift register. As a word-line is enabled, the row of cells is connected to bit-lines and thereby to peripheral circuitry at the top of the linear. Further digital circuitry produces enabling signals that control analogue switching or sense circuitry to enable the signals on consecutive bit-lines to be connected to the output. Again the shift register function may be used to realize the digital circuitry.

Shown in FIG. 1 is a column of an active sensor based on passive pixel cells 110. A passive pixel cell 110 has a very simple structure consisting of a photodiode PD with an associated capacitance Cd and a transistor switch MR. The photodiodes are connected to a common bus 120 through the switches MR1, MR2, . . . , MRx that are located inside each cell. The column bus is coupled to the input of a charge amplifier (not shown), which provides a signal Vo that indicates the level of illumination collected by a one of the photodiodes PD.

However, a common problem of sensor arrays is spatial noise, which results form spatial variation between pixel cells in an array that are manifested itself as pattern noise in the image. Spatial noise is one of the major sources of degradation in image array performance. Spatial noise is often due to photo response non-uniformity, which results from the gain variations between photocells and column amplifiers when the photo sensors are illuminated. The magnitude of this form of spatial noise is signal-dependent.

### SUMMARY OF THE INVENTION

It is an object of the present invention to provide apparatus and a method for output signals in combination of image data signal and corresponding bias signal of each photocell in a linear CMOS sensor.

It is another object of the present invention to provide apparatus and a method output signals of a linear CMOS sensor applied on a scanner. The output signals are alternating current output signals that can prevent large bias variations among the photocells.

In the present invention, apparatus for output in combination of an image data signal and a corresponding bias signal in a linear complementary metal-oxide-semiconductor sensor and a plurality of photocells therein is provided. The apparatus comprises a plurality of enabling circuits for enabling a plurality of first switch devices of the photocells. Each first switch device is on a bypass of a access from the photocell to a second switch device and the second switch device on an access for the photocell to a common bus. A method for output in combination of an image data signal and a corresponding bias signal in a linear complementary metal-oxide-semiconductor sensor of a scanner is provided. The method comprises providing a plurality of photocells arranged in a row that each photocell has an access to a common bus controlled by a corresponding first switch device. Each photocell further has a bypass of the access controlled by a corresponding second switch device. The first switch devices are enabled by a plurality of control lines that each control line is from a corresponding AND gate that makes AND operation for a corresponding pixel select line and a common reset line.

### BRIEF DESCRIPTION OF THE DRAWINGS

A better understanding of the invention may be derived by reading the following detailed description with reference to the accompanying drawing wherein:

FIG. 1 is a schematic diagram of a passive photodiode-based cell structure that is employed in prior art of active pixel sensors;

FIG. 2 is a schematic diagram of a photo cell implemented in accordance with the present invention that can be employed in the pixel sensor of a scanner;

FIG. 3 is a timing diagram showing voltage versus time plots of a subset of the signals employed in the preferred pixel sensor;

FIG. 4 is a circuit schematic diagram in an analog front end for correlated double sampling in accordance with the present invention employed in the preferred pixel sensor; and

FIG. 5 is a timing diagram showing voltage versus time plots of an output voltage related with correlated double sampling in accordance with the present invention.

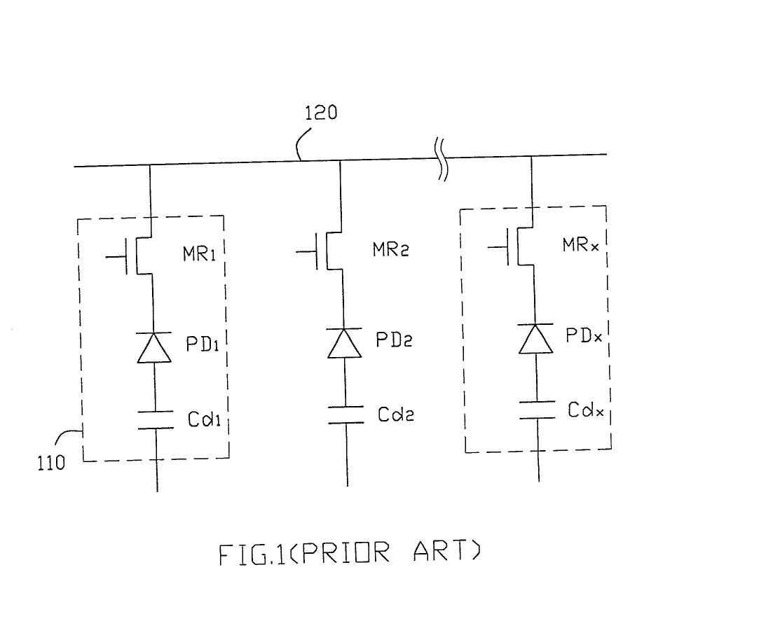

### DESCRIPTION OF THE PREFERRED EMBODIMENT

While the invention is described in terms of a single preferred embodiment, those skilled in the art will recognize that many devices described below can be altered as well as other substitutions with same function and can be freely made without departing from the spirit and scope of the invention.

Furthermore, there is shown a representative portion of a pixel sensor structure of the present invention in enlarged. The drawings are not necessarily to scale, as the thickness of the various layers are shown for clarify of illustration and should not be interpreted in a limiting sense. Accordingly, these regions will have dimensions, including length, width and depth, when fabricated in an actual device.

In the present invention, apparatus for output in combination of an image data signal and a corresponding bias signal in a linear complementary metal-oxide-semiconductor sensor is provided. The apparatus comprises a plurality of photocells in a row of the linear complementary metal-oxide-semiconductor sensor. A plurality of first switch devices that each is on a first access connected to the corresponding photocell and coupled to a voltage supply circuit. A plurality of second switch devices that each is on a second access connected to the corresponding photocell and coupled to in common a bus. A plurality of enabling circuits for enabling the first switch devices that each enabling circuit comprises an AND gate used for AND operation for a corresponding pixel select line and a common reset line. A method for output in combination of an image data signal and a corresponding bias signal for a plurality of photocells in a linear complementary metal-oxide-semiconductor sensor is provided. The method comprises providing a plurality of photocells arranged in a row. Each photocell has an access to a common bus controlled by a corresponding first switch device, and has a bypass of access controlled by a corresponding second switch device. Then the photocells in the row of linear are consequently illuminated. The first switch devices are enabled by a plurality of control lines that each is from a corresponding AND gate that makes AND operation for a corresponding pixel select line and a common reset line, and the second switch devices are also enabled by the pixel select lines.

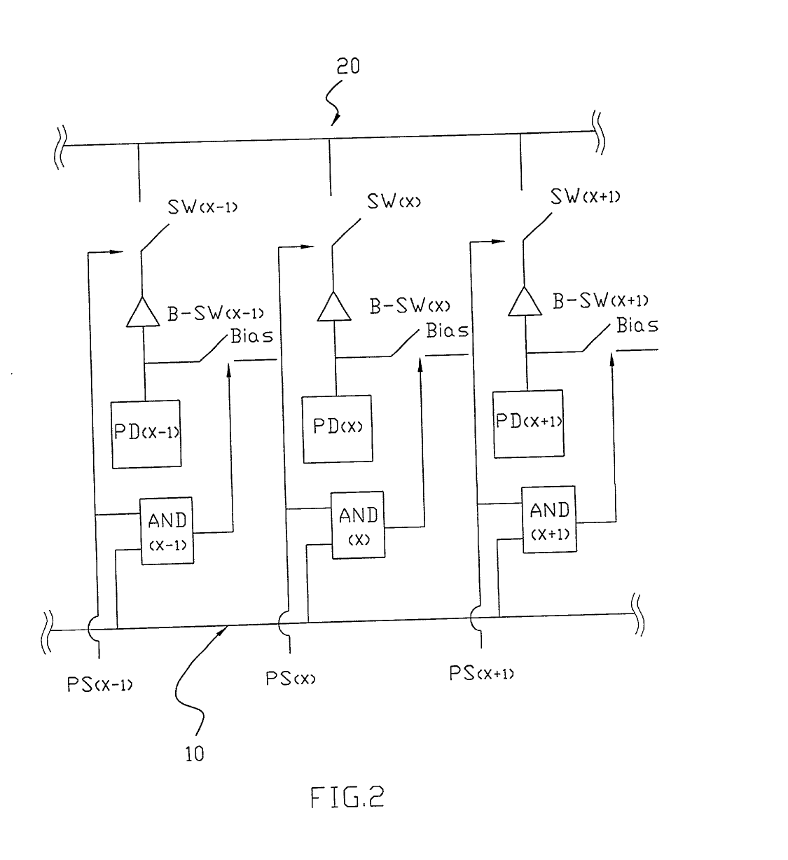

FIG. 2 is a schematic diagram of photocells implemented in accordance with the present invention that can be employed in the pixel sensor of a scanner. Each preferred photocell of linear sensor includes a photodiode PD, a switch SW, a bias switch B-SW and a pixel select PS. All photocells are in common connected to a bus 20 that is coupled to external control circuits(not shown). All photodiodes PD(x−1), PD(x), PD(x+1) . . . , have their corresponding switches SW(x−1), SW(x), SW(x+1) . . . , bias switches B-SW(x−1), B-SW(x), B-SW(x+1) . . . , and pixel selects PS(x−1), PS(x), PS(x+1) . . . In the preferred embodiment, a common reset line 10 added to the corresponding pixel select PS is used for controlling the corresponding bias switch B-SW. On the other hand, pixel select PS(x) controls the corresponding switch SW(x) enabling an access between the photodiode PD(x) and the bus 20.

The reset line 10 cooperated with the pixel select line PS(x) enables bias voltage at same time of enabling an access from photodiode PD(x) to the common bus 20. That is, the data of reading-out includes a scanned image itself and corresponding bias values of all photocells. There are some advantages for the present invention. First, instead of a conventional constant bias voltage (direct current voltage) for all of photodiode PD, each reading-out analog signal is considered with corresponding bias voltage of each photodiode. Each reading-out signal is an output as an alternating current output signal. Each alternating current output signal, subsequently treated with correlated double sampling in an analog front end, can prevent large bias variations that result in not absolute subtractions of bias voltage. Second, the circuit design of the present invention can simplify the external circuit design on subtraction of bias voltage. Furthermore, the resetting and reading-out steps can be simultaneously implemented with respect to the additional circuit design of the present invention.

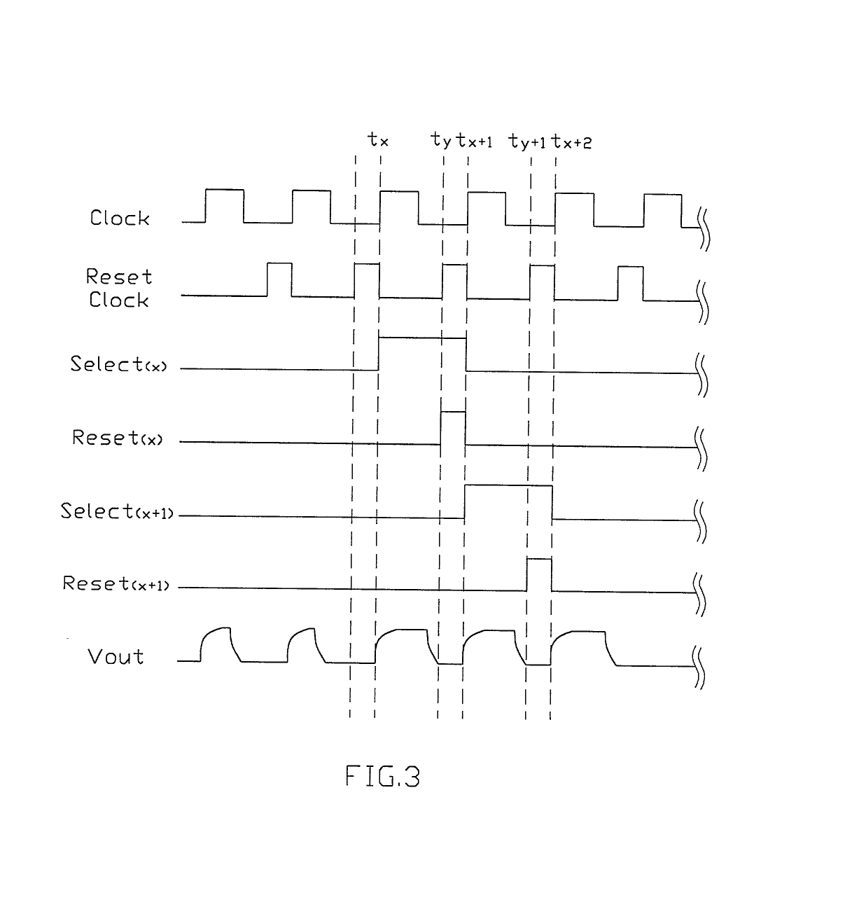

FIG. 3 is a timing diagram showing voltage versus time plots of a subset of the signals employed in the preferred linear pixel sensor. Clock line is a timing control signal for reading photodiode PD, while reset clock line is a control signal for requiring each bias enabled. In the preferred embodiment, at time t(x), the pixel select line select(x) is enabled and the output voltage of image data Vout raises to a high level representing the data signal voltage. When the next signal of reset clock line is sent out at time t(y), the reset line reset(x) is sent a resetting signal according the reset clock line and Vout falls down to a reference level representing the bias voltage. When the signal of reset line reset(x) ends the resetting signal at time t(x+1), the next pixel select line select(x+1) is enabled. If without the additional circuit of the present invention, the output voltage of image data Vout may maintain at a high voltage level, that result in confusion between each signal for each photodiode.

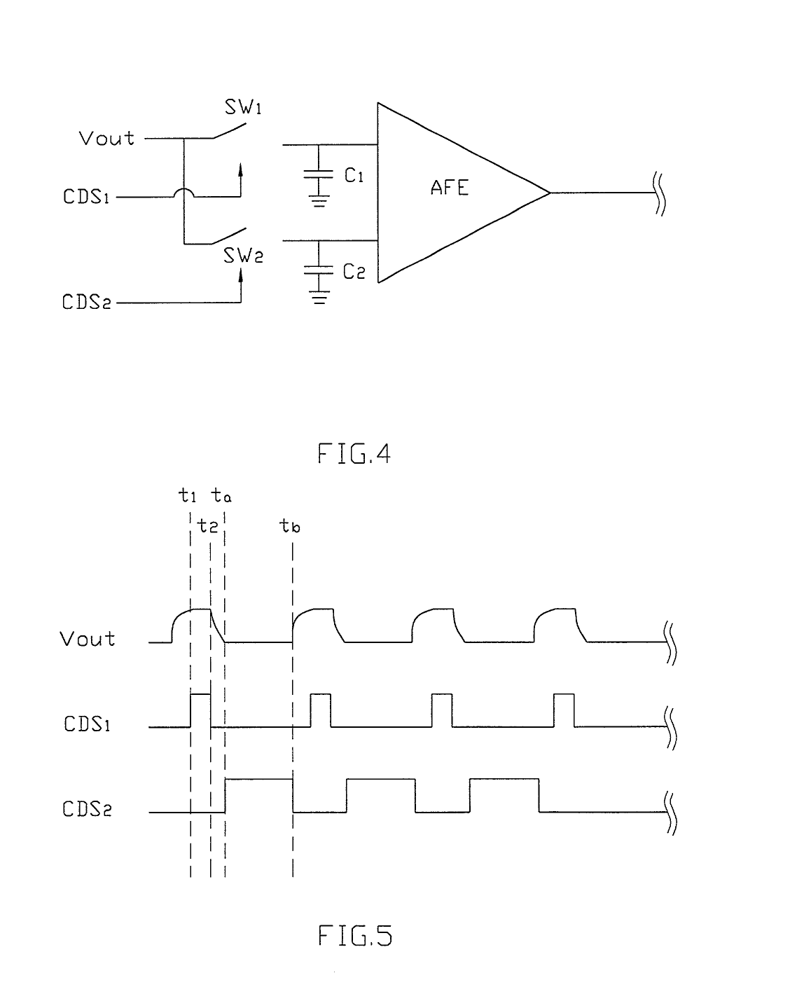

FIG. 4 is depicted an applied circuit related to correlated double sampling in the present invention. The switch SW1 controlled by a first correlated double sampling line CDS1 controls an access for output voltage Vout to the AFE (analog front end). The switch SW2 controlled by a second correlated double sampling line CDS2 also controls the other access for the output voltage Vout to the AFE. Shown as FIG.5, with reference to the output voltage of image data Vout, the signal of CDS1 starts at time t1 and ends at time t2 in accordance with the Vout representing image data signal. The signal of CDS2 starts at time ta and ends at time tb in accordance with the Vout representing bias voltage signal. Accordingly, the output voltage of image data has a reference level that can distinguish each voltage for each photocell.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. It is therefore intended that the appended claims encompass any such modifications or embodiments.

What is claimed is:

1. Apparatus for output in combination of an image data signal and a corresponding bias signal in a linear complementary metal-oxide-semiconductor sensor and a plurality of photocells therein, said apparatus comprising:
a plurality of enabling circuits for enabling a plurality of first switch devices of said photocells, each said first switch device on a bypass of a access from said photocell to a second switch device and said second switch device on an access for said photocell to a common bus.

2. The apparatus of claim 1, wherein said each enabling circuit corresponding said photocell comprises an AND gate used for AND operation for a corresponding pixel select line and a common reset line.

3. The apparatus of claim 2, wherein said second switch is controlled by said corresponding pixel select line.

4. Apparatus for output in combination of an image data signal and a corresponding bias signal in a linear complementary metal-oxide-semiconductor sensor, said apparatus comprising:
a plurality of photocells in a row of said linear complementary metal-oxide-semiconductor sensor;
a plurality of first switch devices, each said first switch device on a first access connected to said corresponding photocell and coupled to a voltage supply circuit, a plurality of second switch devices that each second switch device is on a second access connected to the corresponding photocell and coupled to in common a bus; and
a plurality of enabling circuits for enabling said first switch devices, each enabling circuit comprising an AND gate used for AND operation for a corresponding pixel select line and a common reset line.

5. The apparatus of claim 4, wherein said photocells comprise a plurality of photodiodes.

6. The apparatus of claim 4, wherein said voltage supply circuit is for supplying a bias voltage.

7. A method for output in combination of an image data signal and a corresponding bias signal in a linear complementary metal-oxide-semiconductor sensor of a scanner, said method comprising:
providing a plurality of photocells arranged in a row, each said photocell having an access to a common bus controlled by a corresponding first switch device, and having a bypass of said access controlled by a corresponding second switch device; and
enabling said first switch devices by a plurality of control lines, each said control line from a corresponding AND gate that makes AND operation for a corresponding pixel select line and a common reset line.

8. The method according to claim 7 further comprising
illuminating said photocells in linear sensor; and
enabling said second switch devices by said pixel select lines.

9. The method according to claim 7, wherein said bypass is further coupled to a bias voltage supply circuit.

10. The method according to claim 7, wherein said enabling step comprises:
resetting said photocells; and
reading-out said photocells.

11. The method according to claim 7, wherein said photocells comprise a plurality of photodiodes.

12. A method for output in combination of an image data signal and a corresponding bias signal for a plurality of photocells in a linear complementary metal-oxide-semiconductor sensor, said method comprising:
providing a plurality of photocells arranged in a row, each said photocell having an access to a common bus controlled by a corresponding first switch device, and having a bypass of said access controlled by a corresponding second switch device;
illuminating said photocells in said linear sensor;
enabling said first switch devices by a plurality of control lines, each said control line from a corresponding AND gate that makes AND operation for a corresponding pixel select line and a common reset line; and
enabling said second switch devices by said pixel select lines.

13. The method according to claim 12, wherein said enabling step comprises:
resetting said photocells; and
reading-out said photocells.

14. The method according to claim 12, wherein said photocells comprise a plurality of photodiodes.
